(19) United States
(12) Patent Application Publication
(10) Pub. No.: US 2017/0111451 A1
(43) Pub. Date: Apr. 20, 2017

(54) Methods and Apparatus For Remotely Monitoring Access To Rack Mounted Server Cabinets

(71) Applicant: LiThul LLC, Phoenix, AZ (US)

(72) Inventor: Theodore M. Thul, Phoenix, AZ (US)

(21) Appl. No.: 14/961,176

(22) Filed: Dec. 7, 2015

Related U.S. Application Data
(63) Continuation-in-part of application No. 14/884,593, filed on Oct. 15, 2015.

(51) Int. Cl. H04L 29/08; H05K 5/03; H05K 7/14; H05K 5/02; H04L 29/06; H04L 12/24

(52) U.S. Cl. CPC H04L 67/125; H04L 67/02; H04L 69/16; H04L 41/22; H05K 7/1492; H05K 5/0221; H05K 5/03

(57) ABSTRACT

A server cabinet includes a rack region bounded by a first door and configured to house network devices, a camera configured to surveil an area proximate the door, a lock configured to releasably lock the door in a closed position, and a PDU configured to supply power to the network devices. The PDU also includes a first data port configured to communicate with the camera, a second data port configured to communicate with the lock, and a network connectivity module configured to communicate with a remote computer.

### CROSS REFERENCE TO RELATED APPLICATION

This application is a continuation-in-part of U.S. application Ser. No. 14/884,593, filed Oct. 15, 2015, which is incorporated herein by reference.

### FIELD OF INVENTION

The present invention generally relates to systems and methods for remotely monitoring and controlling access to rack mounted network hardware and, more particularly, to an improved server rack architecture having integrated network connectivity supporting remote access control.

### BACKGROUND

Power distribution units (PDUs) are elongated mechanical housings equipped with multiple electrical outlets for distributing power to racks of computers and networking equipment. Rack mounted strips facilitate power filtering, intelligent load balancing, and remote monitoring and control of power consumption via local area network (LAN) or simple network management protocols (SNMPs).

In a typical server rack installation, a vertically oriented PDU is disposed along a side edge of the rack, with power to the PDU provided through a power cord extending from an uninterruptable power supply (UPS). Presently known PDUs include a network communications processor with an embedded operating system for translating messages, status, and controls between an internal inter-integrated circuit (I2C) bus and an external network. See, for example, the following U.S. patents, the entire disclosures of which are hereby incorporated hereinto:

U.S. Pat. No. 9,166,382, issued Oct. 20, 2015, entitled “Power Distribution Unit and Methods Of Making and Use Including Modular Construction and Assemblies”; U.S. Pat. No. 9,142,971, issued Sep. 22, 2015, entitled “Power Distribution, Management, and Monitoring Systems and Methods”; U.S. Pat. No. 9,104,393, issued Aug. 11, 2015, entitled “Power-Manager Configuration Upload and Download Method and System for Network Managers”; U.S. Pat. No. 9,009,288, issued Apr. 14, 2015, entitled “Remote Power Control System”; U.S. Pat. No. 8,730,695, issued May 20, 2014, entitled “Load Balancing Method and System To Scale DC Output Power By Temperature Of Parallel DC Power Supplies”; U.S. Pat. No. 8,694,272, issued Apr. 8, 2014, entitled “Monitoring Power-Related Parameters In A Power Distribution Unit”; U.S. Pat. No. 8,601,291, issued Dec. 3, 2013, entitled “Power Management Device With Communications Capability and Method Of Use”; U.S. Pat. No. 8,587,950, issued Nov. 19, 2013, entitled “Method and Apparatus For Multiple Input Power Distribution To Adjacent Outputs”; U.S. Pat. No. 8,560,652, issued Oct. 15, 2013, entitled “Remote Power Control System”; U.S. Pat. No. 8,549,067, issued Oct. 1, 2013, entitled “Networkable Electrical Power Distribution Plugstrip With Current Display and Method Of Use”; U.S. Pat. No. 8,549,062, issued Oct. 1, 2013, entitled “Network Remote Power Management Outlet Strip”; U.S. Pat. No. 8,541,907, issued Sep. 24, 2013, entitled “Polyphase Power Distribution and Monitoring Apparatus”; U.S. Pat. No. 8,541,906, issued Sep. 24, 2013, entitled “Polyphase Power Distribution and Monitoring Apparatus”; U.S. Pat. No. 8,527,619, issued Sep. 3, 2013, entitled “Remote Power Control System With Tickle Capability”; U.S. Pat. No. 8,510,424, issued Aug. 13, 2013, entitled “Network-Connected Power Manager For Rebooting Remote Computer-Based Appliances”; U.S. Pat. No. 8,494,661, issued Jul. 23, 2013, entitled “Power Distribution, Management, and Monitoring Systems and Methods”; U.S. Pat. No. 8,489,667, issued Jul. 16, 2013, entitled “Network Power Administration System”; U.S. Pat. No. 8,448,592, issued May 28, 2013, entitled “External Rescue and Recovery Devices and Methods For Underwater Vehicles”; U.S. Pat. No. 8,321,163, issued Nov. 27, 2012, entitled “Monitoring Power-Related Parameters In A Power Distribution Unit”; and U.S. Pat. No. 8,305,737, issued Nov. 6, 2012, entitled “Power Distribution Apparatus With Input and Output Power Sensing and Method of Use”.

Data centers, also known as server farms, typically implement physical security by partitioning the data center into a plurality of zones, with each zone comprising a plurality of server cabinets, and conditioning access to a particular various zone based on the permission level of an individual seeking access to the zone. However, presently known data centers are not equipped to remotely monitor or control access at the cabinet level.

Systems and methods are thus needed which overcome these and other shortcomings in the prior art.

### SUMMARY OF THE INVENTION

An improved server cabinet architecture, sometimes referred to herein as an ark (or Aark™ cabinet system available from APSM Systems at http://www.apsm-jit.com) includes a power distribution unit with integral network connectivity, and one or more security peripheral devices configured to exploit the network connectivity of the PDU to thereby facilitate remotely monitoring and/or controlling access to a particular cabinet. In various embodiments, the cabinet architecture includes an extended chassis which houses servers and networking equipment in a traditional server rack mounting configuration, as well as a network enabled PDU. One or both of a front cabinet door and a back cabinet door includes a lock, camera, biometric device, or the like. The security devices interface with the PDU to allow remote monitoring and/or control of physical access to the network devices housed within the cabinet interior.

The cabinet chassis includes a server side connector module configured to mechanically and electrically mate with the PDU connector module to thereby supply power to the PDU, as well as maintain communication between the PDU and an external network, upon “snap in” installation of the PDU. To facilitate installation, the cabinet chassis may include a pivot mechanism for guiding the PDU connector module into manual engagement with the server side connector module. In this way, the PDU may be integrated into the cabinet chassis as a plug-n-play power and network communications device.

Various embodiments also provide a software application running on a server which may be local to or remote from the monitored cabinet. The application receives and processes data from the one or more peripheral security devices associated with the monitored cabinet, and my provide real time status information, alerts, summary information, remote and/or local storage of logged events, to users on a desk top, mobile (e.g., tablet), or hand held device. The application may also be configured to interact with the security devices to thereby remotely control access to the cabinet. In this way, the system may deter or even prevent unauthorized intrusion and the attendant cyber security risks.

Other embodiments provide a server cabinet system including integrated power distribution and remote access monitoring and security features, and a user application for interactively building custom systems and configuring them on line. For example, a user may use the application to: i) select a rack (e.g., chassis); ii) select the servers (e.g., 2U, 4U, 6U), switches, power supplies, and other hardware; iii) algorithmically determine the position of each item in the rack (e.g., higher heat output devices near the bottom); iv) select the appropriate PDUs; v) determine the optimum cord lengths for the devices; vi) determine which device plug go into which outlets on the PDU; vii) select peripheral devices (e.g., camera, locks); viii) configure the network devices and security devices, including configuring the electrical and mechanical mating between the security devices and the PDU 9 e.g., the network connectivity module associated with the PDU); ix) configure permissions, alerts, and the like; and x) prepare assembly schematics and instructions for shipment.

Various other embodiments, aspects and features are described in greater detail below.

### BRIEF DESCRIPTION OF THE DRAWING FIGURES

The present invention will hereinafter be described in conjunction with the appended drawing figures, wherein like numerals denote like elements, and:

FIG. 1 is a schematic diagram of a prior art system for supplying power to rack mounted servers;

FIG. 2 is a schematic diagram of an improved system including a server rack having an extended width chassis for accommodating a cordless PDU in accordance with various embodiments;

FIG. 3 is an isometric view of a server rack having an expanded frame to receive one or more rack mounted PDUs in accordance with various embodiments;

FIG. 4 is a rear elevation view of the server rack of FIG. 3 in accordance with various embodiments;

FIG. 5 is a perspective view of a server rack with a cordless PDU installed therein in accordance with various embodiments;

FIG. 6 is a perspective view of a PDU pivotably mounted within a server rack in accordance with various embodiments;

FIG. 7 is a schematic diagram illustrating the alignment and engagement of a PDU to its mating, rack mounted server side connector module in accordance with various embodiments

FIG. 8 is a perspective view of a PDU including a network connectivity module, including close up views of the PDU side connector mount and base pivot mount in accordance with various embodiments;

FIG. 9 is a detailed schematic view of the base pivot mount assembly of FIG. 8 in accordance with various embodiments;

FIG. 10 is an exploded view of the PDU side connector mount and rack mounted server side connector module of FIGS. 5 and 7 in accordance with various embodiments;

FIG. 11 is a perspective view of components of FIG. 10, shown in the engaged (installed) position in accordance with various embodiments;

FIG. 12 is a schematic layout diagram of a data center including security devices configured to monitor and control access at the cabinet level in accordance with various embodiments;

FIG. 13 is an isometric view of a cabinet system including remotely monitored cabinet-level access security devices in accordance with various embodiments;

FIG. 14 is a schematic layout diagram of a server cabinet access control system including a server having front and back access doors with each door including a camera and a remotely monitored lock, and an application server configured to present a graphical user interface (GUI) at a mobile device in accordance with various embodiments; and

FIG. 15 is a flow chart illustrating a method for operating a remote access application for a server cabinet system in accordance with various embodiments.

### DETAILED DESCRIPTION OF PREFERRED EXEMPLARY EMBODIMENTS

Various embodiments of the present invention relate to an improved server rack assembly including integrated power distribution and access control systems. The server rack frame includes a first region configured to support a plurality of network computing components (e.g., servers, routers) having a standard width dimension. The frame also includes one or more extended regions configured to house a manually removable power supply. In contrast to prior art PDUs, PDUs of the present invention include a docking mechanism for mechanically and electrically mating with a power source affixed to the frame, and a guide mechanism (e.g., a pivot) for facilitating the manual installation and removal of the PDU from the server frame.

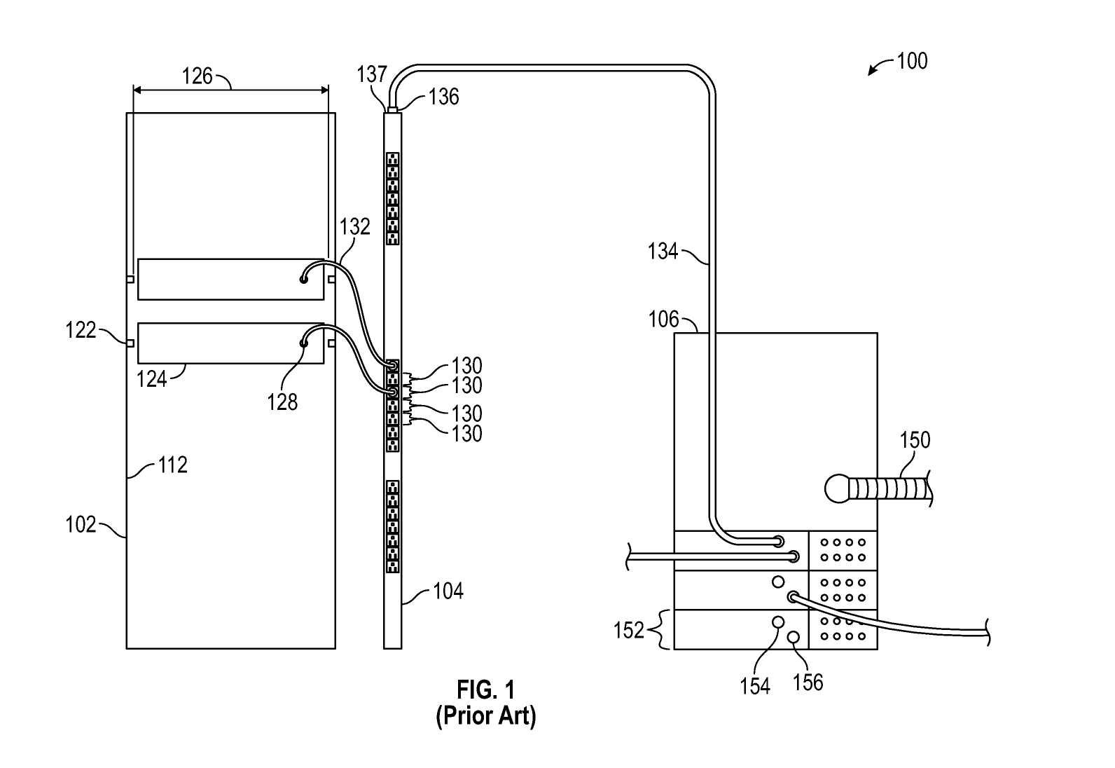

Referring now to FIG. 1, a prior art power distribution system 100 includes a server rack 102, a PDU 104, and a power supply 106. The server rack 102 includes a plurality of rails 122 for (e.g., slidably) mounting respective servers 124, with the rails 122 being secured to or integrated into oppositely disposed interior panels 112 and separated by a nominal distance 126 generally corresponding to the width of servers 124. In this context, the term “rail” refers to any mechanism or technique for securing a hardware component within the server rack such as screws, bolts, quick release mechanisms, fasteners, or the like. Power is supplied from the PDU 104 to each server 124 at a power connection 128.

More particularly, the PDU 124 may comprise any suitable power strip, PDU, or other device available at, for example, www.datacentenesources.com, www.apc.com, www.servertech.com, and www.globalindustrial.com. A typical PDU 104 may include an elongated rectangular metal housing with a plurality of female electrical outlets 130 extending along a front surface, and a power cord 134 terminating at a rubber or plastic grommet 136 or other suitable connection proximate a top end 137 of the PDU. Although not shown in FIG. 1, many PDUs also include various ports for facilitating network connectivity, monitoring, and control such as, for example, wide area network (WAN), local area network (LAN), and Ethernet protocols. The power cord 134 supplies power to the PDU from the power supply 106, as described in more detail below.

The power supply 106 may be any suitable power source such as a data center compatible uninterruptible power supply (UPS) available form, for example, www.emersonnetworkpowder.com, www.apc.com, www.eaton.com, and www.servertech.com. A typical power supply 106 may include an input power cable 150 (source power), and a plurality of output power modules 152, each having a “Phase A” output terminal 154 and a “Phase B” output terminal. In the illustrated embodiment, the power cord 134 supplies power to the PDU from the “Phase A” output terminal 154.

With continued reference to FIG. 1, in presently known installations PDUs are associated with server racks on an ad hoc basis, often being secured to the cabinet with zip ties, electrical tape, or simple placed in an unsecured manner between adjacent cabinets. Consequently, power cords extending from the UPS to the various PDUs often impede human access, impose visual clutter, and otherwise increase entropy within the server rack environment. Improved power distribution systems, arrangements, components, and methodologies are thus needed which overcome these limitations.

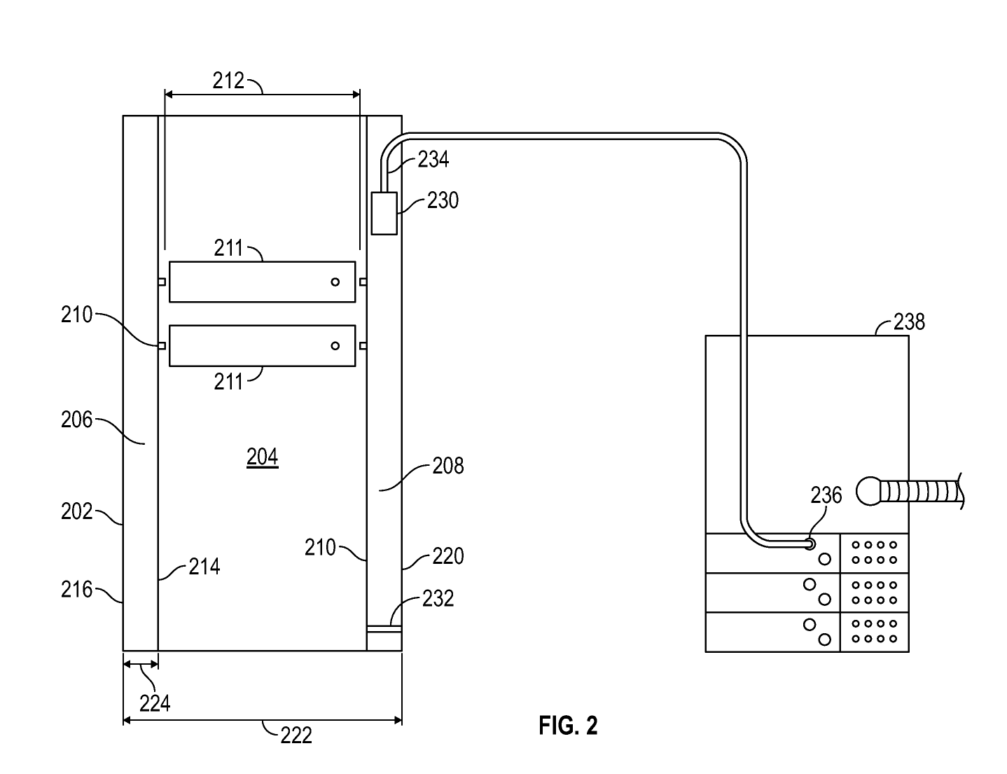

FIG. 2 is a schematic diagram of an improved system including a server rack having an extended width chassis for accommodating a cordless PDU in accordance with various embodiments. In this context, the term “cordless” refers to a PDU according to the present invention that is configured to receive power from an external power supply via a connection module that is integral with the PDU, as opposed to traditional prior art PDUs which receive power from an external power supply via a flexible power cord. Alternatively, the term “cordless” refers to a component that lacks an external flexible electrical cord. More particularly, a rear elevation view of a server cabinet 202 illustrates an internal rack region 204 defined by a left wall panel 214 and a right wall panel 218, each bearing a plurality of rails 210 configured to support server hardware components 211. For purposes of this discussion, the nominal width 212 of the internal rack region 204 corresponds to the distance between the left and right rails 210, which generally corresponds to the nominal width (left-to-right dimension in FIG. 2) of a server 211. In various embodiments, the width 212 is in the range of 17.5 to 20.5 inches, and preferably about 19 inches.

The rack 202 further includes one or more bus regions 206, 208 configured to receive a PDU, described in greater detail below. In the illustrated embodiment, the first bus region 206 is bounded by the left wall panel 214 and a first outer wall 216; the second bus region 208 is bounded by the right wall panel 218 and a second outer wall 220. Each bus region thus exhibits a width dimension 224 which generally corresponds to the width of a PDU, while allowing some clearance to facilitate installation and removal of the PDU from the bus region. In various embodiments, the width 224 is in the range of 1 to 3 inches, and preferably about 1.75 inches.

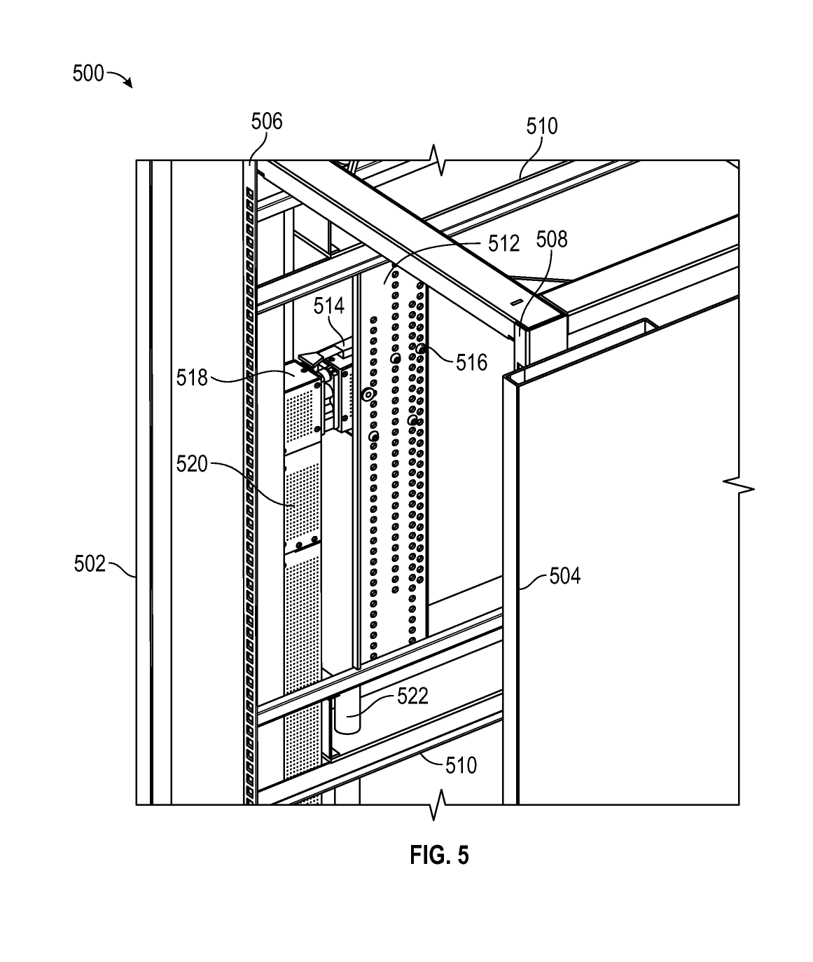

In various embodiments, a bus region (e.g., 206, 208) may include a server side power connection module 234 configured to mate with a corresponding PDU side power connection module (not shown in FIG. 2), as described in greater detail below in conjunction with FIGS. 5, 7, 10, and 11. In addition, a bus region may include a mechanism 232 to facilitate the manual insertion and/or removal of the PDU from the bus region such as, for example, a pivot pin, ramp, slide, journal, notch, bearing, or the like.

With continued reference to FIG. 2, a power cable 234 supplies power from a connection 236 of a power supply 238 to the PDU via the server side power connection module 234, as generally described above in connection with FIG. 1.

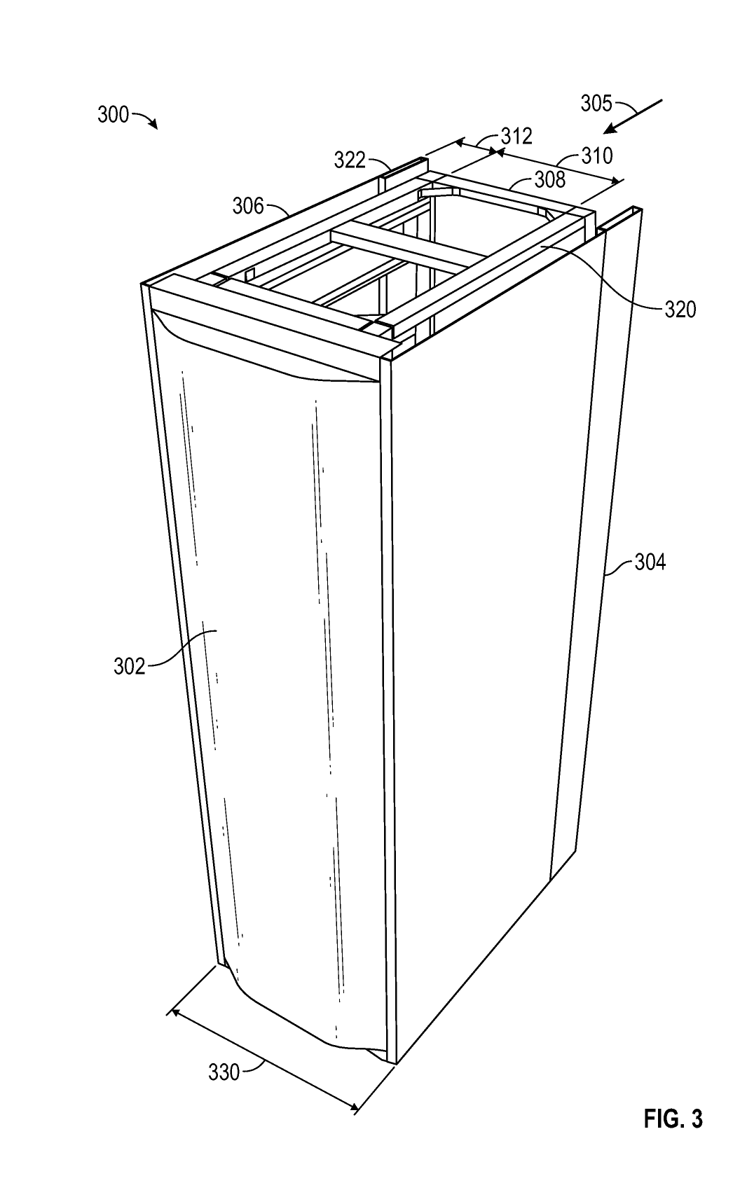

Referring now to FIG. 3, a server rack cabinet 300 includes a front panel 302, typically comprising a transparent door permitting visual inspection of the servers contained within the cabinet, a left outside wall 304 (when viewed from the rear of the cabinet along vector 305), a right outside wall 306, and a frame structure 308. The frame structure 308 preferable includes a server region defined by a first support member 320 and an oppositely disposed second support member 322 separated from the first support member by a width dimension 310 (generally analogous to dimension 212 in FIG. 2). One or more frame extensions define a corresponding bus region between a support member and an outside wall having a width dimension 312 (generally analogous to dimension 224 in FIG. 2). The outside walls 304, 306 are separated by a distance 330 (generally analogous to dimension 222 in FIG. 2).

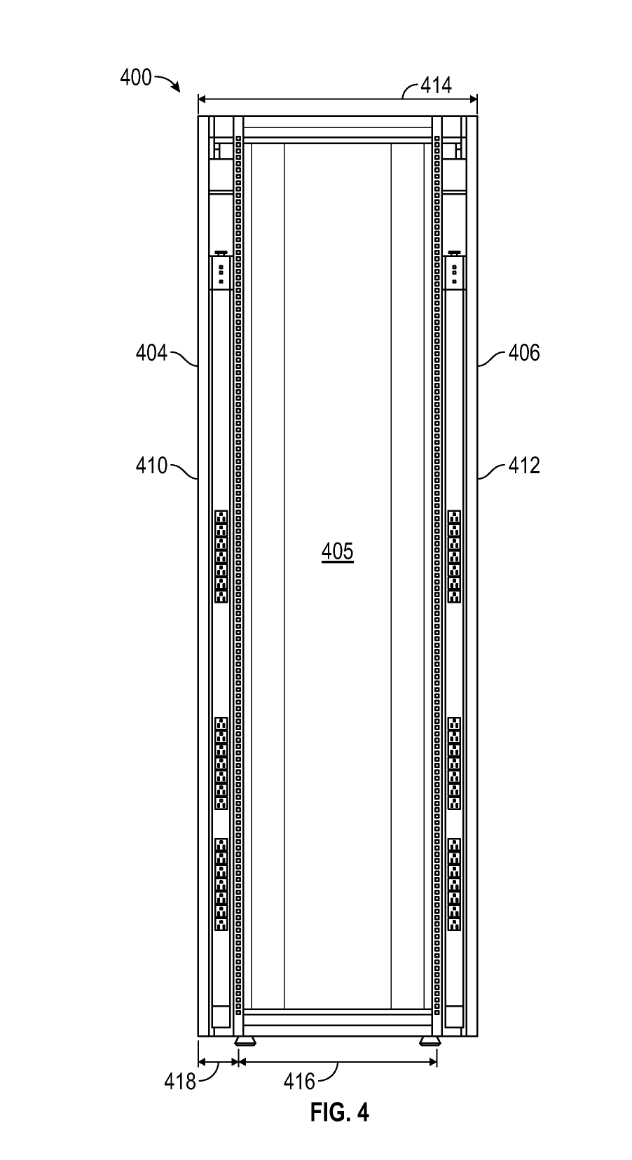

FIG. 4 is a rear view of a cabinet 400 taken along line 305 of FIG. 3. More particularly, the cabinet 400 includes outside walls 404, 406 separated by a distance 414 (generally analogous to dimensions 222 and 330), and respective frame members 410, 412 separated by a distance 416 (generally analogous to dimensions 212 and 310) and defining an interior server region 405. A bus enclosure is disposed between each frame member and it's adjacent outside wall, the bus enclosure having a width 418 (generally analogous to dimensions 224 and 312).

FIG. 5 is a perspective view of a server cabinet 500 with a cordless PDU 520 installed therein in accordance with various embodiments. In particular, the cabinet 500 includes respective outer wall panels 502, 504, respective server bracket members 506 and 508 having a plurality of guide rails 510 connected thereto and configured to support server and other network computing hardware (not shown in FIG. 5), a server connector module mounting plate 512, and a power cord conduit 522. A server connector module 514 is shown secured to the mounting plate 512 by fasteners 516. As shown, the mounting plate 512 extends between two vertically adjacent rails 510; alternatively, the mounting plate may be integrated into the outside wall panel.

A PDU connector module 518 is connected to the top end of the PDU 520, and mechanically and electrically coupled to the server connector module 514. A power cord (not shown in FIG. 5) extends from a UPS to the server connector module 514 via the conduit 522. Those skilled in the art will appreciate that the PDU 520 is disposed within a bus region of the cabinet, generally defined as the region between the server bracket member 506 ant the left outside wall panel 502.

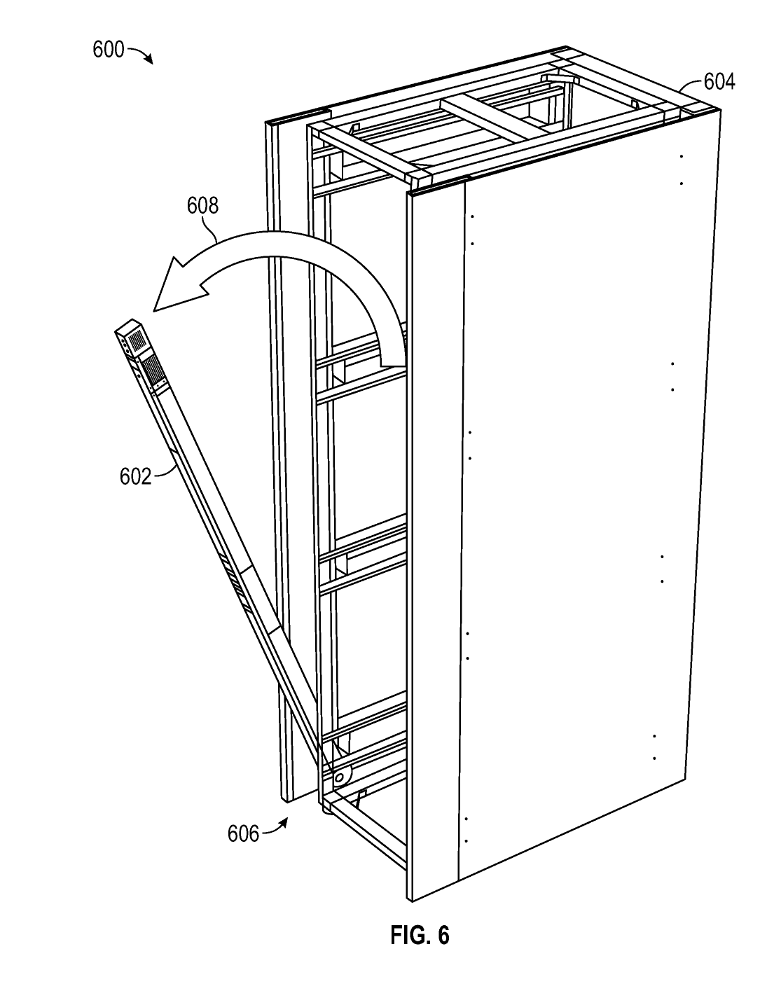

Referring now to FIGS. 6-12, the manner in which the PDU is installed into and removed from the cabinet will now be described in accordance with various embodiments of the present invention. More particularly, FIG. 6 illustrates a power distribution assembly 600 including a PDU 602 removably mounted within a server rack cabinet 604 in accordance with various embodiments. The PDU 602 and/or the cabinet 604 include an attachment mechanism 606 which, in the illustrated embodiment, facilitates rotation of the PDU about the attachment mechanism along an arc 608.

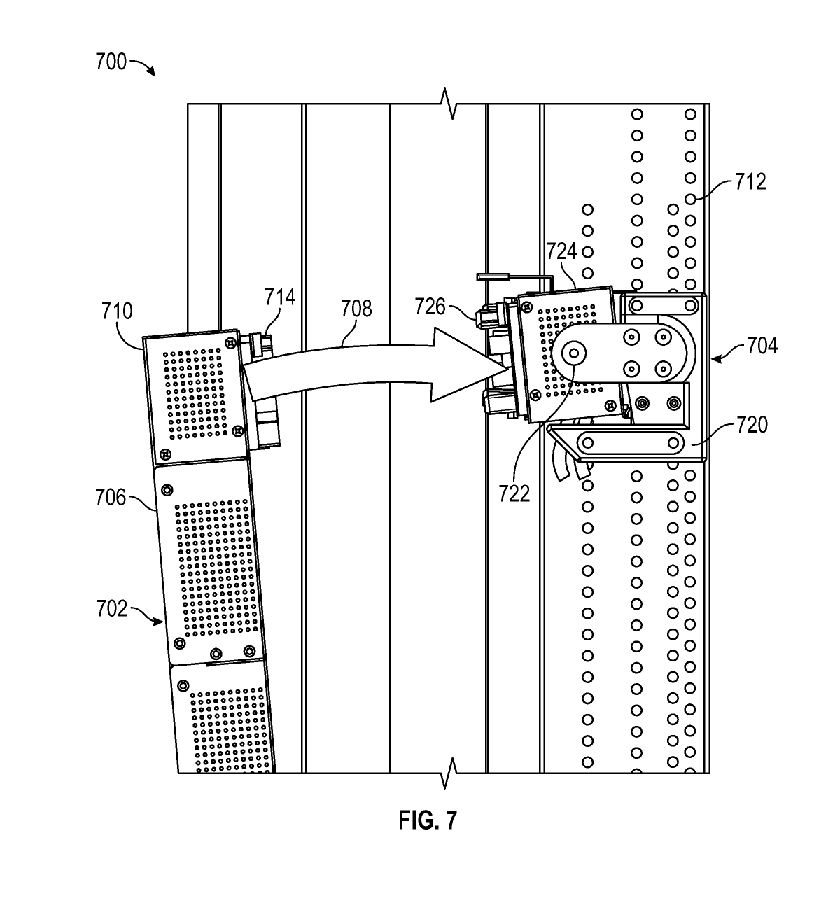

FIG. 7 details the alignment and engagement of a PDU to its mating, rack mounted power supply module in accordance with various embodiments. In particular, an exemplary power supply connection assembly 700 includes a PDU 702 and a supply module assembly 704. The PDU includes a body portion 706 and a PDU connector module 710 secured to one end (e.g., the top) of the PDU. The supply module assembly 704 comprises a server side connector module 724 and a mounting member 720 configured to secure the connector module 724 to a mounting panel 712. When the PDU connector module 710 is drawn along the arcuate path 708, a first electromechanical termination 714 associated with module 710 is brought into engagement with a second electromechanical termination 726 associated with the connector module 724. To facilitate this engagement as module 724 travels along an arcuate path, the connector module 724 is suitably configured to rotate about a pivot 722, and further configured to move (from left to right in FIG. 7) along a slide mechanism 720.

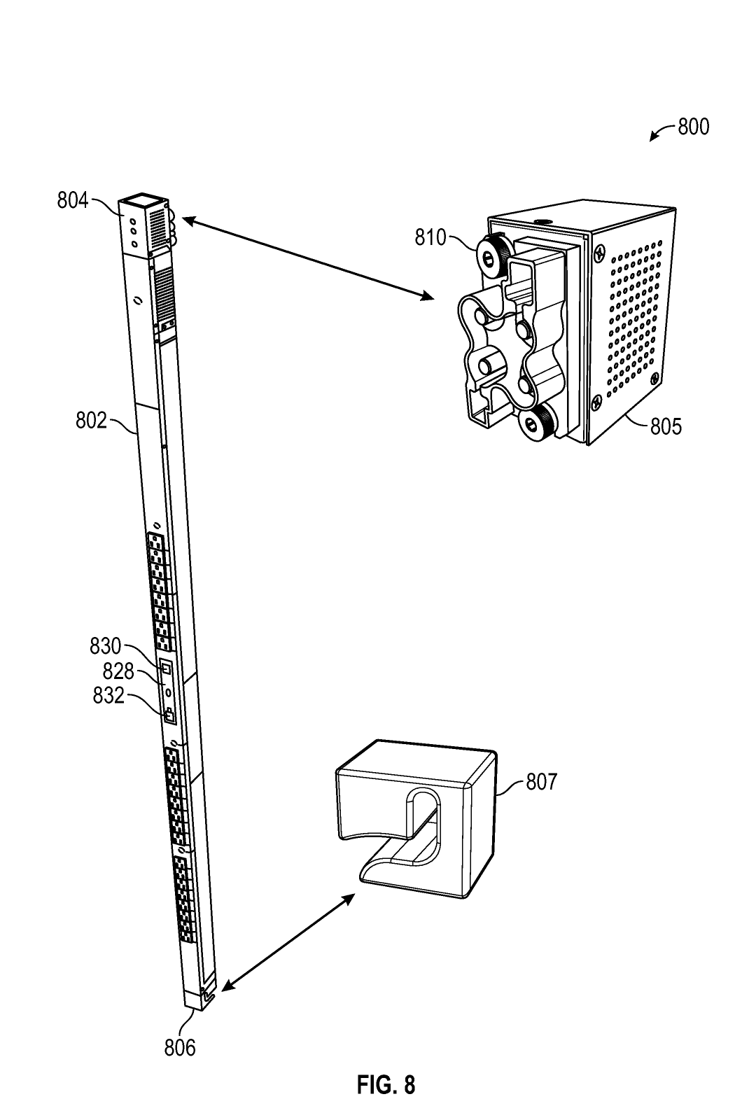

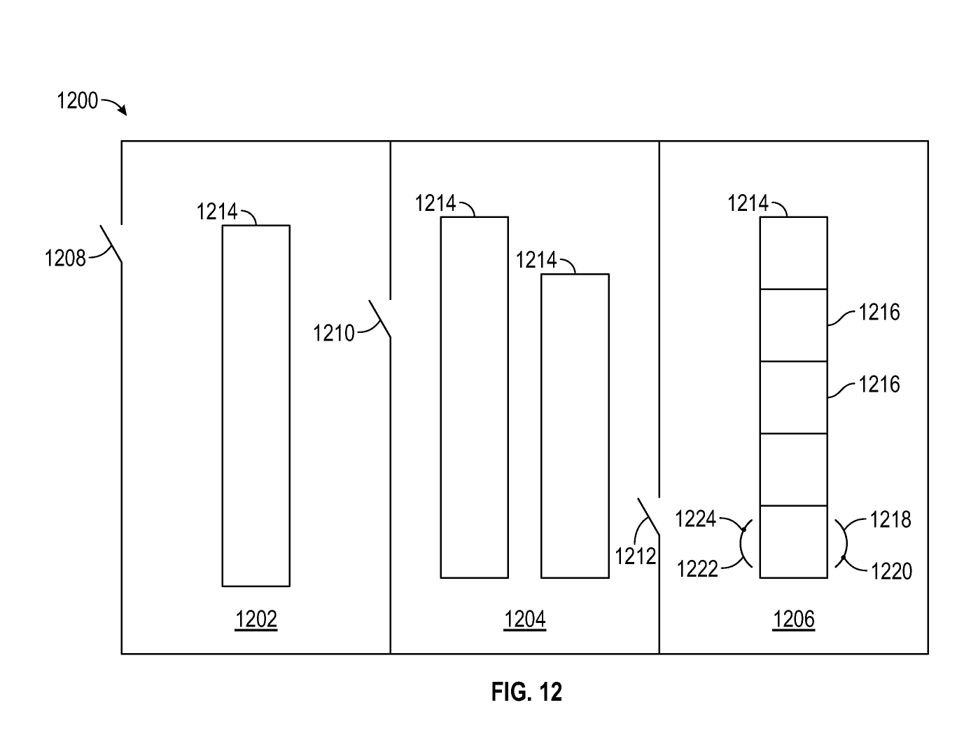

With reference to FIG. 8, a PDU 800 includes a body 802, a PDU side connector module 804 integrated into one end (e.g., the top) of the PDU, a base mount 806 integrated into the opposite (e.g., the bottom) end of the PDU, and a network connectivity module 828. The network connectivity module 828 may include an operating system, an HTML webpage, and a network interface such as an Ethernet 10/100BaseT RJ-45 type socket 832. In this way, the PDU and, specifically, the network connectivity module 828, can support a data connection between a remote user or command console and various peripheral security devices, as described in greater detail below in conjunction with FIGS. 12-15. The network connectivity module 828 preferably uses Internet protocols (e.g., TCP/IP) and supports simple network management protocol (SNMP). In one embodiment, the network connectivity module 828 includes one or more data ports 830 to support wireless or wired data connections with the various security peripheral devices. Alternatively, the data connection between the security devices and the network connectivity module 828 may be integrated with, internal to, or external to the PDU.

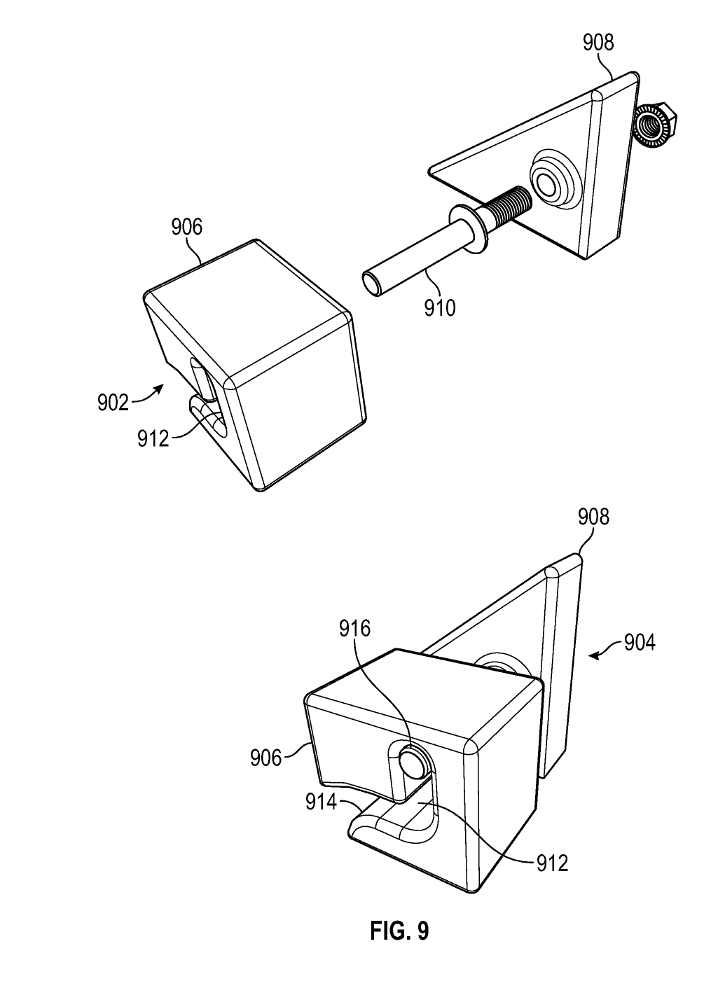

A close up view 805 of the connector module depicts an exemplary electromechanical termination configuration comprising standard male fusion lugs configured to electromechanically engage corresponding female fusion lugs (not shown) associated with the server side connector module. A close up view 807 of the base mount depicts an exemplary pivot mount, described in greater detail below in connection with FIG. 9.

FIG. 9 illustrates an exploded view 902 and an assembled view 904 of a base pivot mounting assembly including a base pivot mount 906, a shaft or dowell 910, and a journaled support member 908 attached to or otherwise integral with the cabinet frame. When installing the PDU into a bus region of a cabinet, the user manually guides the front opening 914 of a relief 912 into engagement with the stationary shaft 910, and urges the bottom of the forward (away from the user) and downwardly, guiding the shaft 901 into engagement with the top portion 916 of the relief 912. In this position, gravity retains the shaft 910 within the upper relief portion 916, allowing the user to pivot the PDU along arrow 708 (FIG. 7) and into engagement with the server side power supply module.

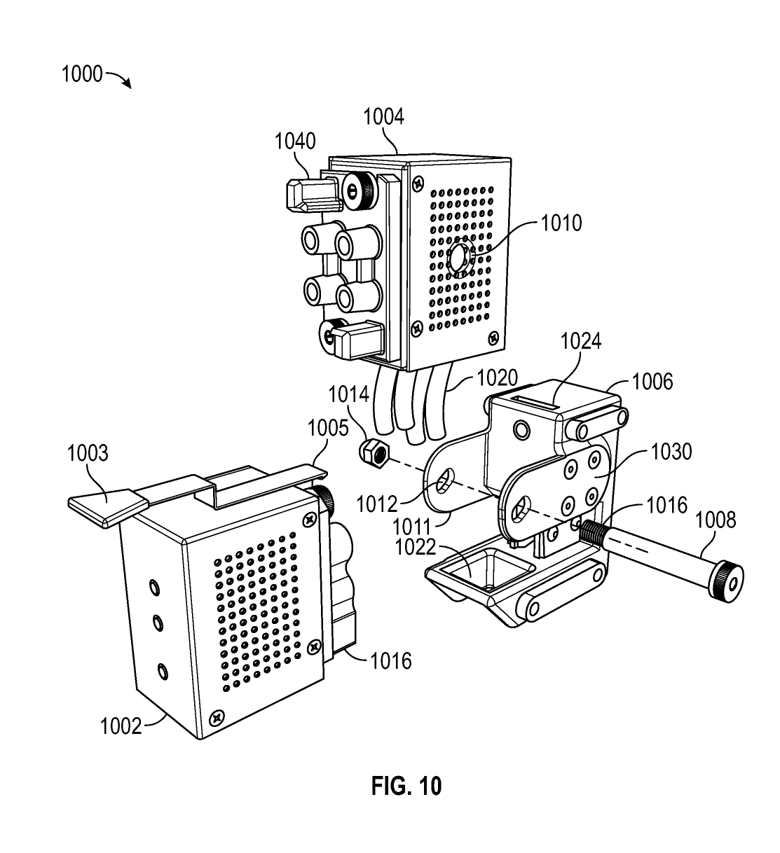

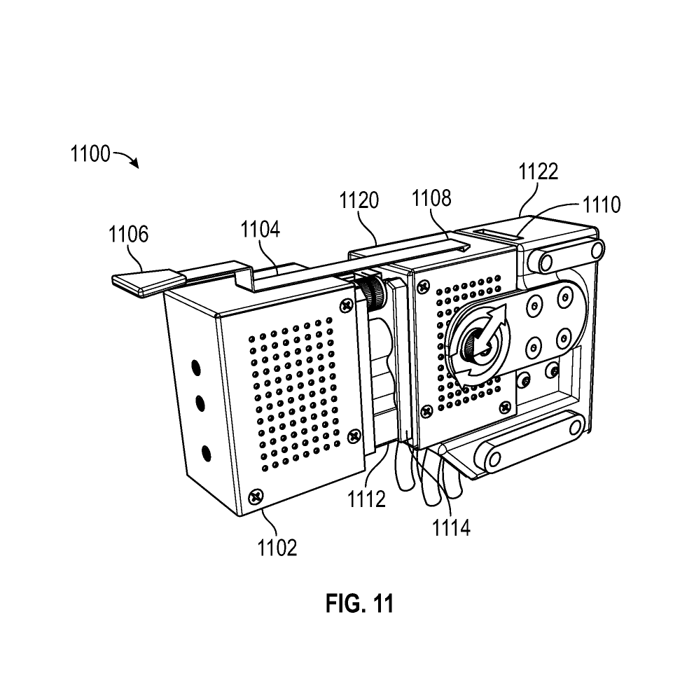

Referring now to FIG. 10, a power supply connection module assembly 1000 includes a PDU side connector module 1002 including a first (e.g., male) engagement interface 1016, a server side connector module 1004 including a second, opposing (e.g., female) engagement interface 1040, and a frame mount 1006. In an embodiment, the frame mount 1006 includes a shaft 1008 and a shaft mount 1011 having a through hole 1012 for supporting the shaft 1008, a slide mechanism 1030, and a bundle guide 1022 through which a power supply/communication cable bundle 1020 connects to the server side connector module 1004. A locking mechanism 1003 attached to the PDU side connector module 1002 includes a tab 1005 configured to mate with a corresponding groove 1024 associated with the frame mount 1006 to releasably lock the mated assembly together, as described in greater detail below in connection with FIG. 11.

With continued reference to FIG. 10 and with momentary reference to FIG. 7, as the PDU side connector module 710, 1002 is manually maneuvered upwardly and to the right, the pivot assembly (e.g., shaft 1008 and shaft mount 1011) and slide mechanism 1030 allow the server side connector module 1004 to track this movement and facilitate the engagement between the first and second engagement interfaces 1016, 1040.

FIG. 11 is a perspective view of the components depicted in FIG. 10, shown in the engaged (installed) position in accordance with various embodiments. More particularly, power supply connection module assembly 1100 includes a PDU side connector module 1102 including a first (e.g., male) engagement interface 1112, a server side connector module 1120 including a second, opposing (e.g., female) engagement interface 1114, and a frame mount 1122. The PDU connector module 1102 further includes a locking mechanism 1104 including a handle 1106 and locking tab 1108 which, when the two modules are fully engaged, seats within a recessed groove or against a raised detent 1110 on the top surface of the frame mount 1122 to thereby maintain locked engagement between the opposing modules until manually released by manipulating the 1106.

FIG. 12 is an exemplary data center 1200 including a first room or zone 1202, a second zone 1204, and a third zone 1206; it will be appreciated that the data center 1200 may have any desired number of zones, sub-zones, and the like, of any desired sizes, shapes, and locations within the data center, and that each zone may have any number of server cabinets. In the illustrated embodiment, an exterior door 1208 provides access to the interior region of the data center, a first interior door 1210 provides access between zone 1202 and zone 1204, and a second interior door 1212 provides access between zone 1204 and zone 1206. In typical prior art systems, the interior doors provide the principal—of not the only—mechanism for controlling access to a group of server cabinets.

With continued reference to FIG. 12, one or more zones each include one or more cabinet arrays 1214, with each array comprising any desired number of server cabinets 1216. In particular, the array 1214 located in zone 1206 includes five (5) cabinets 1216, wherein a single cabinet is sometimes referred to herein as a cabinet assembly, a cabinet system, or a cabinet architecture, particularly when describing the cabinet and its associated external doors and peripheral security devices. Each cabinet 1216 may include one or both of a front door 1220 and a back door 1222, as well as respective front-side and back-side security devices 1220 and 1224. As described in greater detail below, the security devices may be wireless or wired, and may include: video, audio, and or motion surveillance apparatus; radio frequency identification (RFID), keypad, proximity, or other key or entry device such as a finger operated button (FOB); and various biometric devices such as retinal scan, finger or thumb print detectors, voice recognition, and the like.

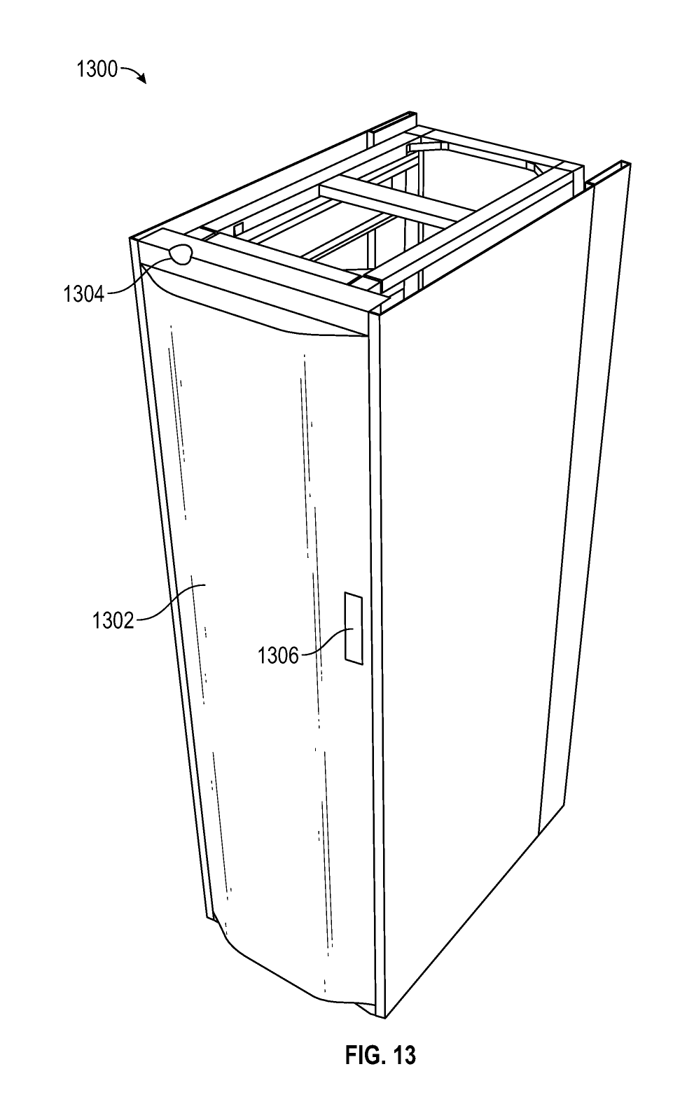

Referring now to FIG. 13, an exemplary cabinet system 1300 includes a front door (also referred to as a front-side door) 1302 having a door lock 1306 and an audiovisual sensor (e.g., camera) 1304 suitably mounted proximate a top portion of the cabinet chassis. In this way, the aforementioned security devices may be configured to provide access monitoring and control at the cabinet level (as opposed to at the zone level); stated another way, by mounting a dedicated camera and/or lock on each cabinet, access may be remotely monitored and/or controlled on a per cabinet basis (as opposed to using a camera and/or door lock to secure an entire room).

Door lock 1306 may comprise any suitable latching or locking mechanism such as, for example, the StealthLock Keyless Cabinet Locking System SL-100 available at http://www.rockler.com; the Kaba E-Plex 5790 Electronic Server Cabinet Lock or the Anviz Biometric L100-II Nanotechnology Fingerprint Lock & Card Reader available at http://www.gokeyless.com; or any of the keyless locks available at http://www.nokey.com/kecatylo.html. The camera 1304 may comprise any suitable audio, video, and/or motion surveillance device such as, for example, those available at http://www.securitycamerasdirect.com/cctv-products.

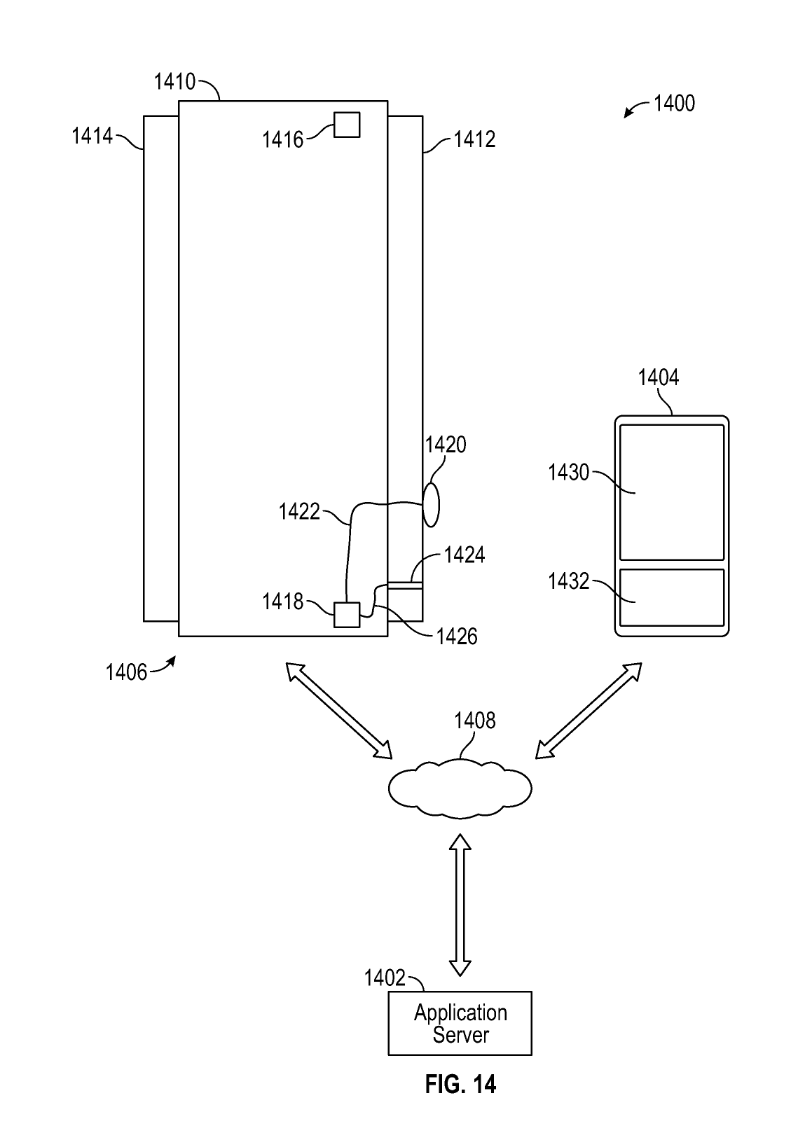

FIG. 14 depicts an exemplary remote access control system 1400 including an application server 1402 configured to run a remote access user application, a client device 1404 configured to display a GUI associated with the application, a cabinet assembly 1406, and a network 1408 (e.g., the internet) for facilitating communication among the application server 1402, the client device 1404, and the cabinet assembly 1406. In the illustrated embodiment, the client device is a mobile telephone, tablet, or other hand held device having a display 1430 and a keypad 1432 to facilitate user interaction with the remote access user application.

With continued reference to FIG. 14, the cabinet assembly 1406 includes a server cabinet 1410 (generally analogous to the server cabinet 202 of FIG. 2 and the server cabinet 300 of FIG. 3, discussed above), a first (e.g., front) access door 1412, a second (e.g., rear) access door 1414, first and second network enabled PDUs 1416 and 1418 (generally analogous to PDUs 602, 702, and 802 described above), a camera 1420 having a data connection 1422 to the PDU, and a lock 1424 having a data connection 1426 to the PDU. In an embodiment, the camera and lock leverage the network connectivity of the PDU to provide data to and receive control signals from the remote access application, and to otherwise interface with the application and the client device 1404.

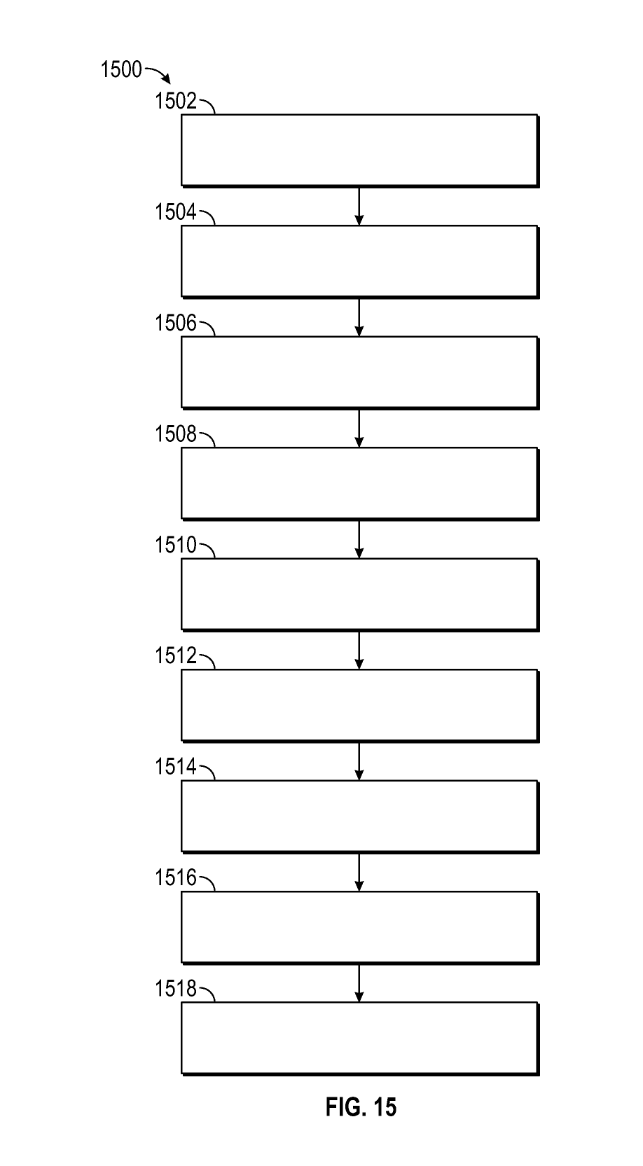

FIG. 15 is a flow chart illustrating a method 1500 for operating a remote access application for a server cabinet system of the type described in FIGS. 12 and 14. The method includes monitoring (Task 1502) the area immediately adjacent the cabinet assembly, for example using any combination of motion, thermal, noise, weight, trip wire, electromagnetic, biometric, or other sensing modalities, and logging an event (Task 1504) when an intrusion is detected within the virtual fence surrounding the cabinet system. If desired, an alert or other status indicator may be sent (Task 1506) to the device 1404 or other monitoring station to inform an administrator that someone has breached the security perimeter around the cabinet (or to update and/or record the status of any other parameter associated with the system). In addition, a photograph, video, or other metric associated with the presence of the individual triggering the virtual fence may be captured, time stamped, stored, and/or sent to the administrator.

The method 1500 further includes detecting (Task 1508) a change in status of the door lock, for example when an authorized or unauthorized user engages the door lock in an attempt to gain access to the interior of the cabinet. In one embodiment, the user may unlock the lock directly; alternatively, a second level of approval (e.g., password) may be required from a remote administrator. In this regard the method may require one or more verification (e.g., biometric) steps to confirm the user's identity (Task 1510) before granting access to the cabinet interior.

Once access is granted, an audio/video or other record may be recorded and stored (Task 1512) for the entire session during which the cabinet is opened, including event logs for all actions taken with respect to equipment added to, removed from, or otherwise manipulated or configured within the cabinet (Task 1514). This may include live streaming to remote viewers of the entire access session, which may also involve the use of multiple cameras movable about multiple respective axes to ensure that all relevant activities are observed and recorded.

The method 1500 further involves monitoring the closing and/or relocking (Task 1516) of the cabinet door when the access session is terminated. In an embodiment, the lock may be remotely secured (Task 1518) in the event the user forgets to or otherwise fails to properly secure the cabinet door when finished.

In a further embodiment, the data connections from the security peripherals may utilize the network connectivity of the PDU, or communicate with the application server independently of the PDU. In either case, a local processor or mini PC such as, for example, a Raspberry Pi™ or Beaglebone™ processing module may be employed to coordinate connecting the peripheral devices to the cloud based or other application server, for example using CAT 5 or other suitable network connectivity protocols. Once the system is set up, a recurring revenue model may be implemented using a Software-as-a-Service (SaaS) model, for example charging periodic service fees as a function of the amount of data flowing through the PDU. In this regard, the application may be configured to present a dashboard metaphor at the client device or at any other desired access portal.

It will also be appreciated that the PDU-side connector and the server-side connector (e.g., items 710 and 724 in FIG. 7) may be configured to include a sufficient number of conductors to supply power to any number of desired peripheral security devices

An elongated power distribution unit (PDU) for use in a rack mounted server cabinet is thus provided. The PDU includes: a plurality of electrical power supply; a network connectivity module configured to facilitate communication between the PDU and a remote computer; and a security connection module configured to communicate data between at least one peripheral security device and the network connectivity module.

In an embodiment, the network connectivity module is compliant with CAT 5 network protocols.

In an embodiment, the at least one peripheral security device comprises at least one of a camera, motion detector, and a cabinet door lock.

4. The PDU of claim 1, wherein the network connectivity module comprises at least one data port configured to communicate with the at least one peripheral security device.

In an embodiment, the network connectivity module further comprises network interface port configured to communicate with the remote computer.

In an embodiment, the network interface port supports Ethernet 10/100Base protocols.

In an embodiment, the network connectivity module comprises an operating system configured to support a web page viewable at the remote computer.

In an embodiment, the network connectivity module is configured to employ TCP/IP internet protocols and support a simple network management protocol (SNMP).

A server cabinet is also provided which includes: a rack region bounded by a first door and configured to house network devices; a camera configured to surveil an area proximate the first door; and a PDU configured to supply power to the network devices. In an embodiment, the PDU includes: a first data port configured to communicate with the camera; and a network connectivity module configured to communicate with a remote computer.

In an embodiment, the server cabinet further includes a first lock configured to releasably lock the first door in a closed position.

In an embodiment, the PDU further comprises a second data port configured to communicate with the first lock.

In an embodiment, the first and second data ports each comprise one of a wireless and a wired connection.

In an embodiment, the network connectivity module is configured to communicate data from the camera and the first lock to the remote computer.

In an embodiment, the network connectivity module is configured to communicate instructions from the remote computer to the camera and the first lock.

In an embodiment, at least one of the first and second data ports is internal to the PDU.

In an embodiment, at least one of the first and second data ports is external to the PDU.

In an embodiment, the rack region is further bounded by a second door having a second lock configured to releasably lock the second door in a closed position, and the PDU further comprises a third data port configured to communicate with the second lock.

A system is also provided for remotely monitoring access to networked computing devices. The system includes: a remote access application configured to run on an application server; a client device configured to display a GUI provided by the remote access application; and a server cabinet assembly. The server cabinet assembly includes: a rack region bounded by a door and configured to house network devices; a camera configured to surveil an area proximate the door; a lock configured to releasably lock the door in a closed position; and a PDU configured to supply power to the network devices. The PDU includes a first data port configured to communicate with the camera, a second data port configured to communicate with the lock, and a network connectivity module configured to communicate with the remote access application.

In an embodiment, the GUI is configured to alert a user of the client device of an access event.

In an embodiment, the GUI is configured to permit a user of the client device to build and configure the server cabinet assembly.

While there has been illustrated an enabling description of various embodiments including the best mode known to the inventors, it will be understood by those skilled in the art that various changes and modifications may be made and equivalents may be substituted for various elements without departing from the scope of the invention. Therefore, it is intended that the inventions disclosed herein not be limited to the particular embodiments disclosed, but that the invention will include all embodiments falling within the literal and equivalent scope of the appended claims.

I claim:

1. An elongated power distribution unit (PDU) for use in a rack mounted server cabinet, the PDU comprising:
a plurality of electrical power supply;
a network connectivity module configured to facilitate communication between the PDU and a remote computer; and
a security connection module configured to communicate data between at least one peripheral security device and the network connectivity module.

2. The PDU of claim 1, wherein the network connectivity module is compliant with CAT 5 network protocols.

3. The PDU of claim 1, wherein the at least one peripheral security device comprises at least one of a camera, motion detector, and a cabinet door lock.

4. The PDU of claim 1, wherein the network connectivity module comprises at least one data port configured to communicate with the at least one peripheral security device.

5. The PDU of claim 4, wherein the network connectivity module further comprises network interface port configured to communicate with the remote computer.

6. The PDU of claim 5, wherein the network interface port supports Ethernet 10/100Base protocols.

7. The PDU of claim 1, wherein the network connectivity module comprises an operating system configured to support a web page viewable at the remote computer.

8. The PDU of claim 7, wherein the network connectivity module is configured to employ TCP/IP internet protocols and support a simple network management protocol (SNMP).

9. A server cabinet comprising:
a rack region bounded by a first door and configured to house network devices;
a camera configured to surveil an area proximate the first door;
a PDU configured to supply power to the network devices, the PDU comprising:
a first data port configured to communicate with the camera; and
a network connectivity module configured to communicate with a remote computer.

10. The server cabinet of claim 9, further comprising a first lock configured to releasably lock the first door in a closed position.

11. The server cabinet of claim 10, wherein the PDU further comprises a second data port configured to communicate with the first lock.

12. The server cabinet of claim 11, wherein the first and second data ports each comprise one of a wireless and a wired connection.

13. The server cabinet of claim 12, wherein the network connectivity module is configured to communicate data from the camera and the first lock to the remote computer.

14. The server cabinet of claim 13, wherein the network connectivity module is configured to communicate instructions from the remote computer to the camera and the first lock.

15. The server cabinet of claim 14, wherein at least one of the first and second data ports is internal to the PDU.

16. The server cabinet of claim 14, wherein at least one of the first and second data ports is external to the PDU.

17. The server cabinet of claim 9, wherein the rack region is further bounded by a second door having a second lock configured to releasably lock the second door in a closed position, wherein the PDU further comprises a third data port configured to communicate with the second lock.

18. A system for remotely monitoring access to networked computing devices, comprising:
a remote access application configured to run on an application server;
a client device configured to display a GUI provided by the remote access application; and
a server cabinet assembly including:
a rack region bounded by a door and configured to house network devices;
a camera configured to surveil an area proximate the door;
a lock configured to releasably lock the door in a closed position; and
a PDU configured to supply power to the network devices, the PDU comprising a first data port configured to communicate with the camera, a second data port configured to communicate with the lock, and a network connectivity module configured to communicate with the remote access application.

19. The remote monitoring system of claim 18, wherein the GUI is configured to alert a user of the client device of an access event.

20. The remote monitoring system of claim 18, wherein the GUI is configured to permit a user of the client device to build and configure the server cabinet assembly.
